(19) United States
(12) Patent Application Publication
(10) Pub. No.: US 2026/0068713 A1
(43) Pub. Date: Mar. 5, 2026

(54) SEMICONDUCTOR PACKAGE AND MANUFACTURING METHOD OF THE SAME

(71) Applicant: Samsung Electronics Co., Ltd., Suwon-si (KR)

(72) Inventors: MyungDo Cho, Suwon-si (KR); MINKYU KIM, Suwon-si (KR)

(21) Appl. No.: 19/063,936

(22) Filed: Feb. 26, 2025

(30) Foreign Application Priority Data
Aug. 29, 2024 (KR) 10-2024-0117131

(51) Int. Cl. H01L 23/538; H01L 21/48; H01L 23/31; H01L 25/18

(52) U.S. Cl. CPC H01L 23/5386

(57) ABSTRACT

The present disclosure relates to a semiconductor package and a manufacturing method thereof. An embodiment of the present disclosure provides a semiconductor package including a redistribution layer including a first surface and a second surface facing away from each other, an external connection structure on the first surface, a plurality of semiconductor chips arranged on the second surface, and a molding material covering the plurality of semiconductor chips. The redistribution layer includes a plurality of redistribution patterns, a plurality of redistribution vias connecting the plurality of redistribution patterns, and an insulating layer surrounding the plurality of redistribution patterns and the plurality of redistribution vias. The insulating layer includes a first insulating layer, a second insulating layer, and an intermediate insulating layer positioned between the first insulating layer and the second insulating layer. The plurality of redistribution patterns includes a first set of redistribution patterns, a second set of redistribution patterns, and an intermediate set of redistribution patterns positioned between the first set of redistribution patterns and the second set of redistribution patterns. The intermediate insulating layer includes a material that is different from those of the first insulating layer and the second insulating layer. The intermediate insulating layer surrounds sidewalls of the intermediate set of redistribution patterns.

### CROSS-REFERENCE TO RELATED APPLICATION

This application claims priority to and the benefit of Korean Patent Application No. 10-2024-0117131, filed in the Korean Intellectual Property Office on Aug. 29, 2024, the entire contents of which are incorporated herein by reference.

### BACKGROUND

### 1. Field

The present disclosure relates to a semiconductor package and a manufacturing method thereof.

### 2. Description of the Related Art

In the semiconductor industry, semiconductor packages mounted in an electronic device are being miniaturized, made more lightweight, and thinned, while at the same time, having high-speed, multifunction, and large-capacity, in line with a demand for miniaturization and light weight of electronic devices. Accordingly, semiconductor chips have increasingly fine-spaced input/output (I/O) pins, and it is technically and physically very difficult to directly connect fine-spaced I/Os of such semiconductor chips to the regular-spaced I/Os of a substrate, and thus a redistribution layer (RDL) interposer has been developed and used as an intermediate medium to electrically connect the fine-spaced I/Os of the semiconductor chips to the regular-spaced I/Os of the substrate.

### SUMMARY

Embodiments provide a semiconductor package and a manufacturing method, capable of improving reliability and electrical characteristics.

An embodiment of the present disclosure provides a semiconductor package including a redistribution layer including a first surface and a second surface facing away from each other, an external connection structure on the first surface, a plurality of semiconductor chips arranged on the second surface, and a molding material covering the plurality of semiconductor chips. The redistribution layer includes a plurality of redistribution patterns, a plurality of redistribution vias, and an insulating layer surrounding the plurality of redistribution patterns and the plurality of redistribution vias. Each of the plurality of redistribution vias is connected to a corresponding one of the plurality of redistribution patterns The insulating layer includes a first insulating layer, a second insulating layer, and an intermediate insulating layer positioned between the first insulating layer and the second insulating layer. The plurality of redistribution patterns includes a first group of redistribution patterns, a second group of redistribution patterns, and an intermediate group of redistribution patterns positioned between the first group of redistribution patterns and the second group of redistribution patterns. The intermediate insulating layer includes a material that is different from those of the first insulating layer and the second insulating layer. The intermediate insulating layer surrounds sidewalls of the intermediate group of redistribution patterns.

An embodiment of the present disclosure provides a semiconductor package including a redistribution layer including a first surface and a second surface facing away from each other, an external connection structure on the first surface, a plurality of semiconductor chips arranged on the second surface, and a molding material covering the plurality of semiconductor chips. The redistribution layer includes a plurality of redistribution patterns, a plurality of redistribution vias, and an insulating layer surrounding the plurality of redistribution patterns and the plurality of redistribution vias. Each of the plurality of redistribution vias is connected to a corresponding one of the plurality of redistribution patterns. The insulating layer includes a first insulating layer, a second insulating layer, and an intermediate insulating layer positioned between the first insulating layer and the second insulating layer. The plurality of redistribution patterns includes a first group of redistribution patterns, a second group of redistribution patterns, and an intermediate group of redistribution patterns. The intermediate group of redistribution patterns is positioned lower than the second group of redistribution patterns and positioned higher than the first group of redistribution patterns. The first insulating layer surrounds sidewalls of the first group of redistribution patterns, the second insulating layer surrounds sidewalls of the second group of redistribution patterns, and the intermediate insulating layer surrounds sidewalls of the intermediate group of redistribution patterns. A material of the intermediate insulating layer has a lower coefficient of thermal expansion than materials of the first insulating layer and the second insulating layer.

An embodiment of the present disclosure provides a manufacturing method for a semiconductor package, including forming a plurality of external connection patterns, forming a first insulating layer on the plurality of external connection patterns, forming a first group of redistribution vias and a first group of redistribution patterns surrounded by the first insulating layer, forming an intermediate insulating layer by laminating a sheet-shaped insulating layer on the first group of redistribution patterns, forming an intermediate group of redistribution vias and an intermediate group of redistribution patterns surrounded by the intermediate insulating layer, grinding a surface of the intermediate insulating layer and a surface of each of the intermediate group of redistribution patterns, forming a second insulating layer on the intermediate group of redistribution patterns, forming a second group of redistribution vias and a second group of redistribution patterns surrounded by the second insulating layer, forming a plurality of redistribution connection pads on the second group of redistribution patterns, and bonding a chip connection terminal of each of stacking a plurality of semiconductor chips on the redistribution connection pads. In the manufacturing method, according to some embodiments, the forming of the intermediate insulating layer includes forming a first sub-insulating layer, and forming a second sub-insulating layer. Further, the forming of the intermediate group of redistribution vias includes forming via holes by patterning the first sub-insulating layer, and forming a first conductive material to fill the via holes. Further, the forming of the intermediate group of redistribution patterns includes forming openings by patterning the second sub-insulating layer, and forming a second conductive material to fill the openings. The second sub-insulating layer is formed to cover the via hole, and the first and second conductive materials are formed by performing a plating process. In the manufacturing method, according to some embodiments, before the grinding of the surface of each redistribution pattern of the intermediate group of redistribution patterns, the first conductive material has a first thickness in a vertical direction, and the second conductive material has a second thickness in the vertical direction. The first thickness is less than the second thickness. After the grinding of the surface of each redistribution pattern of the intermediate group of redistribution patterns, the intermediate insulating layer has a third thickness in the vertical direction. The third thickness is less than the second thickness. In the manufacturing method, according to some embodiments, the first group of redistribution vias include a plurality of first sets of redistribution vias, each set of the first sets of redistribution vias includes first individual redistribution vias located at the same height level as each other in a direction perpendicular to the surface of the intermediate insulating layer, the second group of redistribution vias include a plurality of second sets of redistribution vias, each set of the second sets of redistribution vias includes second individual redistribution vias located at the same height level as each other in a direction perpendicular to the surface of the intermediate insulating layer, a number of the plurality of first sets of redistribution vias is from one to three, and a number of the plurality of second sets of redistribution vias is from one to three.

An embodiment of the present disclosure provides a semiconductor package including a redistribution layer including a first surface and a second surface facing away from each other, and a plurality of semiconductor chips arranged on the second surface. The redistribution layer includes a plurality of redistribution pattern layers, a plurality of redistribution via layers, and an insulating layer surrounding the plurality of redistribution pattern layers and the plurality of redistribution via layers. The insulating layer includes a first insulating layer, a second insulating layer, and an intermediate insulating layer positioned between the first insulating layer and the second insulating layer. The plurality of redistribution pattern layers includes a first group of redistribution patterns, a second group of redistribution patterns, and an intermediate group of redistribution patterns. The intermediate group of redistribution patterns is positioned lower than the second group of redistribution patterns and positioned higher than the first group of redistribution patterns. The first insulating layer surrounds sidewalls of the first group of redistribution patterns, the second insulating layer surrounds sidewalls of the second group of redistribution patterns, and the intermediate insulating layer surrounds sidewalls of the intermediate group of redistribution patterns. The intermediate insulating layer is formed of a first material having a first coefficient of thermal expansion. The first insulating layer is formed of a second material having a second coefficient of thermal expansion. The second insulating layer is formed of a third material having a third coefficient of thermal expansion. The first coefficient of thermal expansion is less than the second coefficient of thermal expansion and the third coefficient of thermal expansion. The intermediate group of redistribution patterns include one or more ground patterns, which are configured to be electrically connected to ground.

According to the embodiments, reliability of a semiconductor package may be improved and an electrical characteristic may be improved.

### BRIEF DESCRIPTION OF THE DRAWINGS

FIG. 1 illustrates a cross-sectional view of a semiconductor package according to an embodiment.

FIG. 2 illustrates an enlarged view of a region P1 in FIG. 1.

FIG. 3 illustrates an enlarged view of a region P2 in FIG. 2.

FIG. 4 illustrates a cross-sectional view of a semiconductor package according to an embodiment.

FIG. 5 illustrates a cross-sectional view of a semiconductor package according to an embodiment.

FIG. 6 to FIG. 13 illustrate cross-sectional views showing a manufacturing method for a semiconductor package according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present invention.

To clearly describe the present disclosure, parts that are irrelevant to the description are omitted, and like numerals refer to like or similar components, and duplicate descriptions may be omitted for the purpose of simplicity and clarity throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on,” “contacting” or “in contact with” another element (or using any form of the word “contact”), there are no intervening elements present at the point of contact.

Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Further, throughout the specification, the phrase “in a plan view” means when an object portion is viewed from above, and the phrase “in a cross-sectional view” means when a cross-section taken by vertically cutting an object portion is viewed from the side.

Items described in the singular herein may be provided in plural, as can be seen, for example, in the drawings. Thus, the description of a single item that is provided in plural should be understood to be applicable to the remaining plurality of items unless context indicates otherwise. In the drawings, though only one item is labeled, as can be understood from the description of example embodiments, there may be a plurality of items.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

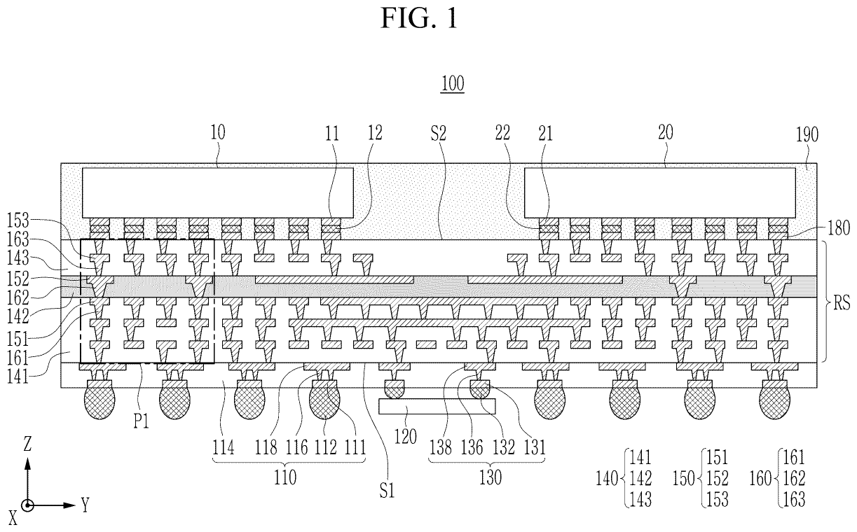

Hereinafter, a semiconductor package according to an embodiment will be described with reference to FIG. 1 to FIG. 3.

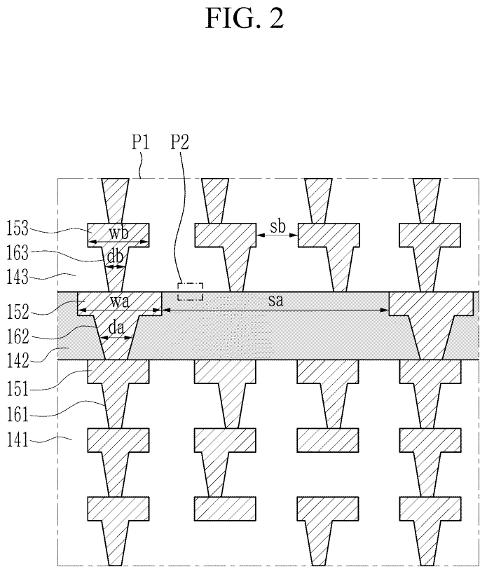

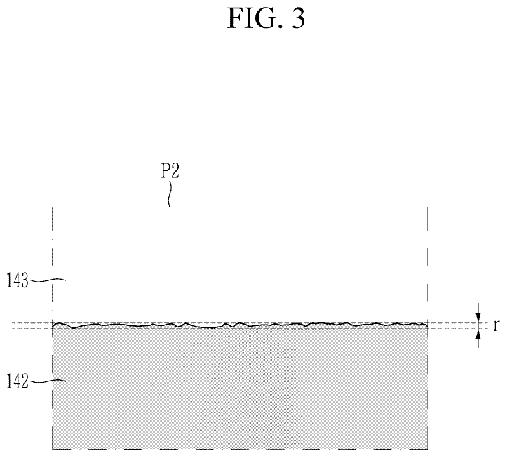

FIG. 1 illustrates a cross-sectional view of a semiconductor package according to an embodiment. FIG. 2 illustrates an enlarged view of a region P1 in FIG. 1. FIG. 3 illustrates an enlarged view of a region P2 in FIG. 2.

Referring to FIGS. 1 to 3, the semiconductor package 100 according to an embodiment may include a redistribution layer RS including a first surface S1 and a second surface S2 facing away from each other, an external connection structure (which may be an external connection layer) 110 disposed on the first surface S1, a plurality of semiconductor chips 10 and 20 disposed on the second surface S2, and a molding member (which may be molding material) 190 covering the semiconductor chips 10 and 20 on the redistribution layer RS.

The external connection structure 110 may be a composite layer, which includes an external connection insulating layer 114, a plurality of external connection patterns 118, a plurality of external connection vias 116, a plurality of first external connection members (which may be external connection pads) 111, and a plurality of second external connection members (which may be external connection terminals) 112. The external connection structure 110 may connect the semiconductor package 100 to an external device (e.g., a printed circuit board (PCB)).

The external connection insulating layer 114 and the external connection patterns 118 may be positioned on the first surface S1. The external connection insulating layer 114 may be positioned between the external connection patterns 118. The external connection insulating layer 114 may insulate the external connection patterns 118 from each other. The external connection insulating layer 114 may surround lower surfaces and opposite sides (sidewalls) of the external connection patterns 118.

The first external connection members 111 may be positioned on the external connection insulating layer 114. The first external connection members 111 may be separated (spaced apart) from the external connection patterns 118 by the external connection insulating layer 114. The external connection insulating layer 114 may be positioned between the external connection members 111. The external connection insulating layer 114 may insulate the first external connection members 111 from each other. The external connection insulating layer 114 may surround lower surfaces and opposite sides of the external connection member 111. The first external connection members 111 may be arranged to face the external connection patterns 118 in a direction Z perpendicular to the first surface S1.

The second external connection members 112 may be respectively positioned on the first external connection members 111. The second external connection members 112 may be directly connected to an outside (e.g., to an external device such as a PCB). In FIG. 1, each of the second external connection members 112 is illustrated as having a ball shape, but the present invention is not necessarily limited thereto. For example, the shape of each of the second external connection members 112 may be changed in various ways.

According to an embodiment, the first external connection members 111 may be connected to the external connection patterns 118 by the external connection vias 116. Each of the external connection vias 116 may be formed integrally with a corresponding one of the external connection patterns 118. The external connection vias 116 may have a shape protruding from lower surfaces of the respective external connection patterns 118. The external connections vias 116 may contact upper surfaces of the first external connection members 111. The external connection vias 116 may extend through the external connection insulating layer 114 in the direction Z. The external connection insulating layer 114 may surround sidewalls of the external connection vias 116.

According to an embodiment, each of the external connection patterns 118 may be formed integrally with a corresponding one of the external connection vias 116, and may be disposed on the external connection vias 116. An upper surface of each of the external connection patterns 118 may be flat.

The external connection patterns 118, the external connection vias 116, the first external connection members 111, and the second external connection members 112 may include a conductive material. For example, the external connection patterns 118, the external connections via 116, and the first external connection members 111 may each include at least one of copper, aluminum, tungsten, nickel, zinc, gold, silver, platinum, titanium, or an alloy thereof, but the present invention is not limited thereto. For example, the second externally connected members 112 may include at least one of tin, silver, lead, nickel, copper, or an alloy thereof, but the present invention is not limited thereto.

According to an embodiment, the semiconductor package 100 may include a passive element (a passive device such as a capacitor, a resistor, etc.) 120 mounted on a first surface of the semiconductor package 100 on which the external connection structure 110 is disposed. The semiconductor package 100 may include an additional connection structure 130 that connects the passive elements 120 to the semiconductor package 100. The additional connection structure 130 may include a plurality of additional connection patterns 138 disposed on the first surface S1, a plurality of first additional connection members (which may be a plurality of additional connection pads) 131 positioned on the external connection insulating layer 114, a plurality of second additional connection members (which may be a plurality of additional connection terminal) 132 positioned respectively on the first additional connection members 131, and an additional connection via 136 extending through the external connection insulating layer 114 to respectively connect the additional connection patterns 138 and the first additional connection members 131.

A size of each of the additional connection patterns 138 may be smaller than a size of each of the external connection patterns 118. The size of each of the additional connection patterns 138 and the size of each of the external connection patterns 118 may be, e.g., widths (horizontal widths) along a direction Y parallel to the first surface S1. The size of each of the first additional connection members 131 may be smaller than a size of each of the first external connection members 111. The size of each of the first additional connection members 131 and the size of each of the first external connection members 111 may be, e.g., widths along the direction Y. A size of each of the second additional connection members 132 may be smaller than a size of each of the second external connection members 112. The size of each of the second additional connection members 132 and the size of each of the second external connection members 112 may be, e.g., maximum widths along the direction Y and maximum heights (vertical height) along the direction Z.

The second additional connection members 132 may be directly connected to the passive element 120. The passive element 120 may include or be, e.g., a decoupling capacitor. Power integrity of the semiconductor package 100 may be improved by mounting a decoupling capacitor in the semiconductor package 100. The decoupling capacitor may be referred to as a land side capacitor as it is mounted at an opposite side of a surface of the semiconductor package 100 on which the semiconductor chip is mounted.

The additional connection patterns 138, the additional connection vias 136, the first additional connection members 131, and the second additional connection members 132 may include a conductive material. For example, the additional connection patterns 138, the additional connection vias 136, and the first additional connection members 131 may include the same material as that of the external connection patterns 118, the external connection vias 116, and the first external connection members 111. For example, the second additional connection members 132 may include the same material as that of the second external connection members 112.

In some embodiments, the additional connection structure 130 may be a part of the external connection layer 110. For example, the additional connection structure 130 and the external connection layer 110 may be simultaneously formed by using the same process steps. For example, a plurality of external connection patterns may include the external connection patterns 118 and the additional connection patterns 138, a plurality of external connection vias may include the external connection vias 116 and the additional connection vias 136, a plurality of external connection pads may include the first external connection members 111 and the first additional connection members 131, and a plurality of external connection terminal may include the second external connection members 112 the second additional connection members 132.

The redistribution layer RS may be a composite layer, which includes a plurality of redistribution patterns 150 which together form redistribution pattern layers, a plurality of redistribution vias 160 connecting the redistribution patterns 150 and which together form redistribution via layers, and an insulating layer 140 surrounding the redistribution patterns 150 and the redistribution vias 160. According to an embodiment, the redistribution pattern layers 150 may include at least 5 redistribution pattern layers. For example, as shown in FIG. 1, a plurality of redistribution patterns 150 may include at least five sets of redistribution patterns, which are stacked sequentially. Each of the five sets of redistribution patterns may include individual redistribution patterns located at the same height level, in a direction perpendicular to the first surface (e.g., direction Z), as each other, and may be described as a redistribution pattern layer.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

According to an embodiment, the insulating layer 140 may include a first insulating layer 141, a second insulating layer 143, and an intermediate insulating layer 142 positioned between the first insulating layer 141 and the second insulating layer 143. The intermediate insulating layer 142 may include a different material from those of the first insulating layer 141 and the second insulating layer 143. The intermediate insulating layer 142 may include a material having a lower thermal expansion coefficient than those of the first insulating layer 141 and the second insulating layer 143. For example, the first insulating layer 141 and the second insulating layer 143 may include a photo imageable dielectric (PID), but the present invention is not necessarily limited thereto. For example, the intermediate insulating layer 142 may include or be formed of Ajinomoto Build-up Film® (ABF) or a prepreg, but the present invention is not necessarily limited thereto.

The redistribution patterns 150 may include at least one first redistribution pattern 151 surrounded by the first insulating layer 141, at least one intermediate redistribution pattern 152 surrounded by the intermediate insulating layer 142, and at least one second redistribution pattern 153 surrounded by the second insulating layer 143. At least one first redistribution pattern 151, at least one intermediate redistribution pattern 152, and at least one second redistribution pattern 153 may be sequentially arranged along the direction Z between the first surface S1 and the second surface S2. At least one first redistribution pattern 151 may be adjacent to the first surface S1. At least one second redistribution pattern 153 may be adjacent to the second surface S2. At least one intermediate redistribution pattern 152 may be positioned between the first redistribution pattern that is most adjacent to the second surface S2 of at least one first redistribution pattern 151 and the second redistribution pattern that is most adjacent to the first surface S1 of at least one second redistribution pattern 153.

In some embodiments, a plurality of first redistribution pattern 151 may be stacked in the direction Z. At least one intermediate redistribution pattern 152 may be stacked in the direction Z. At least one second redistribution pattern 153 may be stacked in the direction Z.

For example, in the intermediate insulating layer 142 (e.g., ABF), there may be only a single set of redistribution patterns. For example, the single set of redistribution patterns may include individual redistribution patterns located at the same height level as each other.

The redistribution vias 160 may include at least one first redistribution via 161 extending through the first insulating layer 141, at least one intermediate redistribution via 162 extending through the intermediate insulating layer 142, and at least one second redistribution via 163 extending through the second insulating layer 143.

At least one first redistribution via 161 may electrically connect the first redistribution pattern 151 and the external connection pattern 118 in the direction Z. When there are the first redistribution patterns 151, at least one first redistribution via 161 may connect the first redistribution patterns 151 in the direction Z. At least one first redistribution via 161 may be stacked in the direction Z.

For example, a plurality of first redistribution patterns 151 may include plural sets of first redistribution patterns, which are stacked sequentially. Each of the plural sets of first redistribution patterns may include individual first redistribution patterns located at the same height level, in a direction perpendicular to the first surface (e.g., direction Z), as each other. At least one of the first redistribution via 161 may connect two individual first redistribution patterns which are located at different height levels.

At least one intermediate redistribution via 162 may connect the intermediate redistribution pattern 152 and the first redistribution pattern 151 in the direction Z. When there are the intermediate redistribution patterns 152, at least one intermediate redistribution via 162 may connect the intermediate redistribution patterns 152 in the direction Z. At least one intermediate redistribution via 162 may be stacked in the direction Z.

For example, in the intermediate insulating layer 142 (e.g., ABF), there may be only a single set of redistribution vias. For example, the single set of redistribution patterns may include individual redistribution vias located at the same height level as each other.

For example, though not shown in the drawings, a plurality of intermediate redistribution patterns 152 may include plural sets of intermediate redistribution patterns, which are stacked sequentially. Each of the plural sets of intermediate redistribution patterns may include individual intermediate redistribution patterns located at the same height level, in a direction perpendicular to the first surface (e.g., direction Z), as each other. At least one of the intermediate redistribution via 162 may connect two individual intermediate redistribution patterns which are located at different height levels.

At least one second redistribution via 163 may connect the second redistribution pattern 153 and the intermediate redistribution pattern 152 in the direction Z. When there are the second redistribution patterns 153, at least one second redistribution via 163 may connect the second redistribution patterns 153 in the direction Z. At least one second redistribution via 163 may connect the second redistribution pattern 153 and the redistribution connection pad 180 described below in the direction Z. At least one second redistribution via 163 may be stacked in the direction Z. For example, though not shown in the drawings, a plurality of second redistribution patterns 153 may include plural sets of second redistribution patterns, which are stacked sequentially. Each of the plural sets of second redistribution patterns may include individual redistribution patterns located at the same height level, in a direction perpendicular to the first surface (e.g., direction Z), as each other. At least one of the second redistribution via 163 may connect two individual second redistribution patterns which are located at different height levels.

According to an embodiment, the intermediate insulating layer 142 may be positioned on up to three first redistribution vias 161 stacked in the direction Z. As shown in FIG. 1, the intermediate insulating layer 142 may be positioned on three first redistribution vias 161 stacked in the direction Z, but the present invention is not necessarily limited thereto. For example, the intermediate insulating layer 142 may be positioned on one first redistribution via 161 or on two first redistribution vias 161 stacked in the direction Z. For example, the plurality of redistribution vias 160 may include plural sets of redistribution vias. Each of the plural sets of redistribution vias may include individual redistribution vias located at the same height level, in a direction perpendicular to the first surface, as each other. A number of sets of redistribution vias, which is positioned higher than the intermediate insulating layer 142, is from one to three. A number of sets of redistribution vias, which is positioned lower than the intermediate insulating layer 142, is from one to three.

According to an embodiment, up to three second redistribution vias 163 may be stacked in the direction Z on the intermediate insulating layer 142. As shown in FIG. 1, two second redistribution vias 163 may be stacked in the direction Z on the intermediate insulating layer 142, but the present invention is not necessarily limited thereto. For example, one second redistribution vias 163 may be positioned on the intermediate insulating layer 142, or two second redistribution vias 163 may be stacked in the direction Z.

The redistribution patterns 150 and the redistribution vias 160 may include a conductive material. For example, the redistribution patterns 150 and the redistribution via 160 may include at least one of copper, aluminum, tungsten, nickel, zinc, gold, silver, platinum, titanium, or an alloy thereof.

According to an embodiment, a wiring width of at least one of the redistribution patterns 150 surrounded by the intermediate insulating layer 142 may be larger than wiring widths of a group of redistribution patterns surrounded by the first insulating layer 141 or the second insulating layer 143. Referring to FIG. 2, a wiring width wa of the intermediate redistribution pattern 152 may be larger than wiring widths wb of the first redistribution pattern 151 and the second redistribution pattern 153.

According to an embodiment, the wiring width of at least one of the redistribution patterns 150 surrounded by the intermediate insulating layer 142 may be larger than the wiring width of a group of redistribution patterns surrounded by the first insulating layer 141 or the second insulating layer 143. Referring to FIG. 2, a width sa between wires of the intermediate redistribution pattern 152 may be larger than widths sb between wires of the first redistribution pattern 151 and the second redistribution pattern 153.

For example, a plurality of redistribution patterns 150 may include a first group of redistribution patterns 151, a second group of redistribution patterns 153, and an intermediate group of redistribution patterns (intermediate redistribution patterns 152) positioned between the first group of redistribution patterns 151 and the first group of redistribution patterns 153. Each of the plurality of intermediate redistribution patterns 152 has a minimum wiring width in a horizontal direction (e.g., direction Y), and a smallest one of the minimum wiring widths of the intermediate group of redistribution patterns 152 in a horizontal direction (e.g., direction Y) may be larger than those of the first group of redistribution patterns 151 and the second group of redistribution patterns 153. Each of adjacent pairs of the plurality of redistribution patterns 150 has a minimum inter-wiring space in a horizontal direction (e.g., direction Y), and a smallest one of the minimum inter-wiring spaces of the intermediate group of redistribution patterns in a horizontal direction (e.g., direction Y) may be larger than those of the first group of redistribution patterns 151 and is larger than those of the second group of redistribution patterns 153.

As described above, the intermediate redistribution pattern 152 may have a relatively less fine wiring pattern than of the first redistribution pattern 151 and the second redistribution pattern 153. According to an embodiment, a portion of at least one redistribution pattern surrounded by the intermediate insulating layer 142 may be configured to be electrically connected to ground (e.g., VSS which is a reference voltage). For example, the intermediate redistribution pattern 152 may include a wire that is electrically connected to ground. The first redistribution pattern 151 and the second redistribution pattern 153, which have relatively finer wiring patterns, may include a wire for transmitting signals. The intermediate redistribution pattern 152 may include wiring that connects the first redistribution pattern 151 and the second redistribution pattern 153, in addition to the wire that is connected to ground.

According to an embodiment, the redistribution vias 160 may include a series of redistribution vias having a common central axis and being stacked in the direction Z perpendicular to the first surface S1. The common central axis may extend along the direction Z. Among the series of redistribution vias stacked in the direction Z, a diameter of at least one redistribution via surrounded by the intermediate insulating layer 142 may be larger than diameters of a group of redistribution vias surrounded by the first insulating layer 141 or the second insulating layer 143. A diameter of a redistribution via may refer to the width along the direction Y.

Referring to FIG. 2, the redistribution vias stacked in the direction Z may include at least one first redistribution via 161 extending through the first insulating layer 141, at least one intermediate redistribution via 162 extending through the intermediate insulating layer 142, and at least one second redistribution via 163 extending through the second insulating layer 143. A diameter da of the intermediate redistribution via 162 may be larger than diameters db of the first redistribution via 161 and the second redistribution via 163.

For example, the plurality of redistribution vias 160 may include a series of redistribution vias, redistribution vias of the series of redistribution vias may have the same central axis in a direction that is perpendicular to the first surface. The series of redistribution vias are stacked in a direction that is perpendicular to the first surface, and may have a first redistribution via having a sidewall surrounded by the intermediate insulating layer 142. The series of redistribution vias has second redistribution vias other than the first redistribution via. The second redistribution vias have sidewalls surrounded by the first insulating layer 141 or the second insulating layer 143. A diameter of the first redistribution via is larger than diameters of the second redistribution vias in a horizontal direction (e.g., direction Y).

Referring to FIG. 3, surface roughness r of a surface of the intermediate insulating layer 142 in contact with the second insulating layer 143 may be about 3 μm or less. For example, some parts of the surface may be relatively higher than other parts, and some parts of the surface may be relatively lower than other parts. Surface roughness of a surface may refer to a height difference between relatively high and relatively low parts of the surface. In some embodiments, the intermediate insulating layer 142 may have a rough surface which is in contact with the second insulating layer 143. An average roughness of the rough surface is equal to or less than 3 μm.

According to an embodiment, materials of the first insulating layer 141 and the second insulating layer 143 have a higher coefficient of thermal expansion than a material of the intermediate insulating layer 142, and thus the first insulating layer 141 and the second insulating layer 143 may exhibit greater warpage than that of the intermediate insulating layer 142. Undulation of each of the first insulating layer 141 and the second insulating layer 143 may be gradually accumulated as they are stacked in the direction Z. Accordingly, reliability of at least one first redistribution via 161 and at least one second redistribution via 163, which are stacked in the direction Z, may be deteriorated as they move away from the first surface S1. Reliability of at least one first redistribution via 161 and at least one second redistribution via 163 stacked in the direction Z may be guaranteed up to three layers. Accordingly, by forming the intermediate insulating layer 142 having a higher coefficient of thermal expansion than the first insulating layer 141 on the first redistribution via 161 of up to three layers, the accumulated undulation in the first insulating layer 141 may be reset and a warpage phenomenon may be reduced to minimize newly occurring undulation. Furthermore, according to the manufacturing method described below, the intermediate insulating layer 142 and the intermediate redistribution pattern 152 may be formed thicker than a target thickness and then formed to the target thickness through a grinding process. Accordingly, surface roughness of a surface of the intermediate insulating layer 142 in contact with the second insulating layer 143 positioned on the intermediate insulating layer 142 may be controlled to about 3 μm or less.

The semiconductor package 100 may include a plurality of redistribution connection pads 180 positioned on the second surface S2 of the redistribution layer RS. The semiconductor chips 10 and 20 arranged on the second surface S2 of the redistribution layer RS may be connected to the redistribution layer RS through the redistribution connection pads 180. For example, the semiconductor chips 10 and 20 may include a first semiconductor chip 10 and a second semiconductor chip 20. A plurality of first connection pads 11 may be arranged on a first surface of the first semiconductor chip 10, and a plurality of first connection members 12 may be respectively arranged on the first connection pads 11. A plurality of second connection pads 21 may be arranged on a first surface of the second semiconductor chip 20, and a plurality of second connection members 22 may be respectively arranged on the second connection pads 21. The first connection members 12 may be connected to some of the redistribution connection pads 180, and the second connection members 22 may be connected to some of the redistribution connection pads 180.

The first connection pads 11, the first connection members 12, the second connection pads 21, and the second connection members 22 may include a conductive material. Each of the first connection pads 11 and the second connection pad 21 may include at least one of, e.g., copper, aluminum, tungsten, nickel, zinc, gold, silver, platinum, titanium or an alloy thereof, but the present invention is not limited thereto. Each of the first connection member 12 and the second connection member 22 may, e.g., include at least one of tin, silver, lead, nickel, copper or an alloy thereof, but the present invention is not limited thereto.

According to an embodiment, the first semiconductor chip 10 and the second semiconductor chip 20 may be electrically connected to each other by the redistribution layer RS. The first semiconductor chip 10 and the second semiconductor chip 20 may be different types of semiconductor chips. The redistribution layer RS that connects different types of semiconductor chips may be referred to as an interposer.

The molding member 190 may cover upper and side surfaces of the semiconductor chips 10 and 20. The molding member 190 may fill a space between lower surfaces of the semiconductor chips 10 and 20 and the second surface S2 of the redistribution layer RS. The molding member 190 may surround the first connection pads 11, the second connection pads 21, the first connection members 12, and the second connection members 22. The semiconductor chips 10 and 20 may be encapsulated on the second surface S2 of the redistribution layer RS by the molding member 190. The molding member 190 may serve to protect the semiconductor chips 10 and 20. For example, the molding member 190 may include an epoxy molding compound (EMC), but the present invention is not limited thereto.

According to an embodiment, the semiconductor package 100 may include an intermediate insulating layer 142 between the first insulating layer 141 and the second insulating layer 143, the intermediate insulating layer 142 including a different material from those of the first insulating layer 141 and the second insulating layer 143. At least one redistribution pattern positioned in the middle of the redistribution patterns 150 may be surrounded by the intermediate insulating layer 142. According to an embodiment, the material of the intermediate insulating layer 142 may have a lower coefficient of thermal expansion than materials of the first insulating layer 141 and the second insulating layer 143.

According to a comparative example in which the insulating layer 140 of the semiconductor package 100 is formed of the materials of the first insulating layer 141 and the second insulating layer 143, reliability of redistribution vias stacked in the direction Z may be guaranteed only for up to three layers. For example, it may be difficult to implement redistribution vias that include four or more redistribution vias, connect at least five redistribution patterns, and are stacked in the direction Z.

The semiconductor package 100 according to an embodiment may reduce warpage occurring while forming five or more redistribution patterns by including the intermediate insulating layer 142 between the first insulating layer 141 and the second insulating layer 143. According to an embodiment, multi-layer stacked redistribution vias connecting five or more redistribution patterns in a vertical direction may be reliably implemented, thereby improving electrical characteristics of the semiconductor package 100.

In some embodiments, the redistribution layer RS may include a plurality of redistribution pattern layers 150, a plurality of redistribution via layers 160, and an insulating layer 140 surrounding the plurality of redistribution pattern layers 150 and the plurality of redistribution via layers 160. The insulating layer 140 may include a first insulating layer 141, a second insulating layer 143, and an intermediate insulating layer 142 positioned between the first insulating layer and the second insulating layer. The plurality of redistribution pattern layers 150 may include a first group of redistribution patterns 151, a second group of redistribution patterns 153, and an intermediate group of redistribution patterns 152. The intermediate group of redistribution patterns 152 may be positioned lower than the second group of redistribution patterns 153 and positioned higher than the first group of redistribution patterns 151. The intermediate insulating layer 142 may be formed of a first material having a first coefficient of thermal expansion. The first insulating layer 141 may be formed of a second material having a second coefficient of thermal expansion. The second insulating layer may be formed of a third material having a third coefficient of thermal expansion. The first coefficient of thermal expansion may be less than the second coefficient of thermal expansion and the third coefficient of thermal expansion. The intermediate group of redistribution patterns 152 may include one or more ground patterns, which may be configured to be electrically connected to ground.

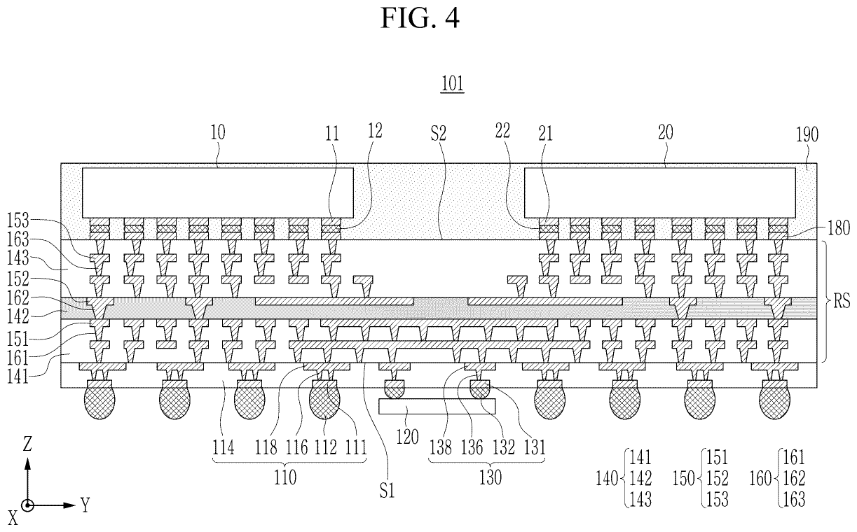

Hereinafter, a modified example of the semiconductor package 100 of FIGS. 1 to 3 will be described with reference to FIG. 4.

FIG. 4 illustrates a cross-sectional view of a semiconductor package according to an embodiment. Hereinafter, regarding the semiconductor package 101 of FIG. 4, duplicate contents with the semiconductor package 100 of FIGS. 1 to 3 will be briefly described or omitted, and differences will be mainly described. The semiconductor package 101 of FIG. 4 may have a different number of first redistribution patterns 151, first redistribution vias 161, second redistribution patterns 153, and second redistribution vias 163 from those in the semiconductor package 100 of FIGS. 1 to 3.

The semiconductor package 101 of FIG. 4 may include two first redistribution patterns 151 and two first redistribution vias 161. Furthermore, the semiconductor package 101 may include two second redistribution patterns 153 and three second redistribution vias 163. The intermediate insulating layer 142 may be positioned on the two first redistribution patterns 151 and the two first redistribution vias 161. The two second redistribution patterns 153 and the three second redistribution vias 163 may be positioned on the intermediate insulating layer 142 of the semiconductor package 101.

For example, the plurality of redistribution vias 160 may include plural sets of redistribution vias. Each of the plural sets of redistribution vias may include individual redistribution vias located at the same height level, in a direction perpendicular to the first surface, as each other. A number of sets of redistribution vias, which is positioned higher than the intermediate insulating layer 142, is three. A number of sets of redistribution vias, which is positioned lower than the intermediate insulating layer 142, is two.

As described above with reference to FIGS. 1 to 3, reliability of at least one first redistribution via 161 and at least one second redistribution via 163 stacked in the direction Z may be guaranteed up to three layers. According to an embodiment, the intermediate insulating layer 142 having a higher thermal expansion coefficient than that of the first insulating layer 141 may be positioned on a first redistribution via 161 of up to three layers stacked in the direction Z, and a second redistribution via 163 of up to three layers stacked in the direction Z may be positioned on the intermediate insulating layer 142. In the embodiment of FIG. 4, the intermediate insulating layer 142 may be positioned on two first redistribution vias 161, and three second redistribution via 163 may be positioned on the intermediate insulating layer 142.

The embodiment of FIG. 4 may have the same effect as that of the embodiment of FIG. 1 to FIG. 3. The semiconductor package 101 according to an embodiment may reduce warpage occurring while forming five or more redistribution patterns by including the intermediate insulating layer 142 between the first insulating layer 141 and the second insulating layer 143. According to an embodiment, multi-layer stacked redistribution vias connecting five or more redistribution patterns in a vertical direction may be reliably implemented, thereby improving electrical characteristics of the semiconductor package 100.

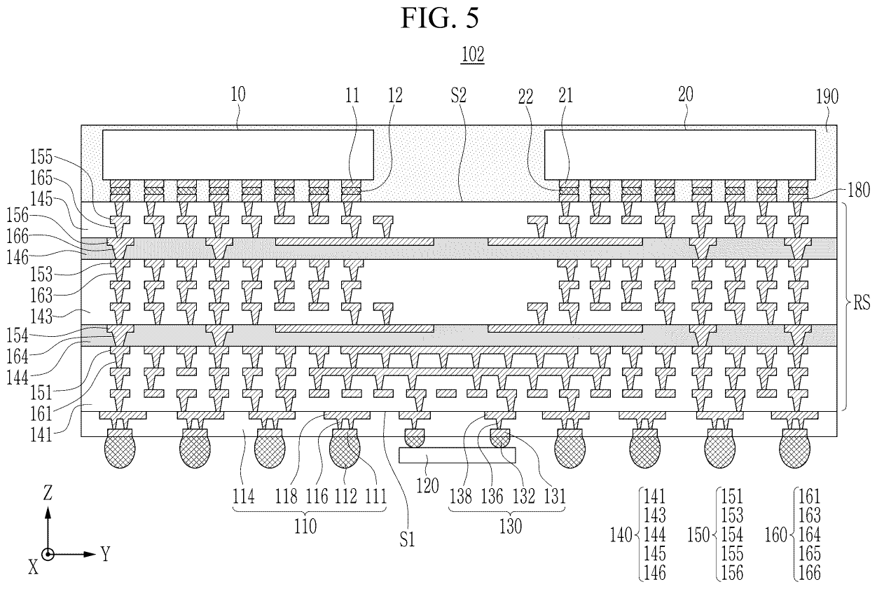

Hereinafter, a modified example of the semiconductor package 100 of FIGS. 1 to 3 will be described with reference to FIG. 5.

FIG. 5 illustrates a cross-sectional view of a semiconductor package according to an embodiment. Hereinafter, regarding the semiconductor package 102 of FIG. 5, duplicate contents with the semiconductor package 100 of FIGS. 1 to 3 will be briefly described or omitted, and differences will be mainly described.

Referring to FIG. 5, the insulating layer 140 of the semiconductor package 102 according to an embodiment may include a first insulating layer 141, a second insulating layer 143, and a third insulating layer 145, and may include a first intermediate insulating layer 144 positioned between the first insulating layer 141 and the second insulating layer 143, and a second intermediate insulating layer 146 positioned between the second insulating layer 143 and the third insulating layer 145. The first insulating layer 141, the second insulating layer 143, and the third insulating layer 145 may include the same material. The first intermediate insulating layer 144 and the second intermediate insulating layer 146 may include a material that is different from those of the first insulating layer 141, the second insulating layer 143, and the third insulating layer 145. According to an embodiment, the first intermediate insulating layer 144 and the second intermediate insulating layer 146 may include a material having a lower thermal expansion coefficient than those of the first insulating layer 141, the second insulating layer 143, and the third insulating layer 145. For example, the first insulating layer 141, the second insulating layer 143, and the third insulating layer 145 may include a PID, and the first intermediate insulating layer 144 and the second intermediate insulating layer 146 may include an ABF or a prepreg, but the present invention is not necessarily limited thereto.

The redistribution patterns 150 may include at least one first redistribution pattern 151 surrounded by the first insulating layer 141, at least one first intermediate redistribution pattern 154 surrounded by the first intermediate insulating layer 144, at least one second redistribution pattern 153 surrounded by the second insulating layer 143, at least one second intermediate redistribution pattern 156 surrounded by the second intermediate insulating layer 146, and at least one third redistribution pattern 155 surrounded by the third insulating layer 145.

For example, the plurality of redistribution patterns 150 may include a first group of redistribution patterns 151, a second group of redistribution patterns 153, and a first intermediate group of redistribution patterns 154 positioned between the first group of redistribution patterns 151 and the second group of redistribution patterns 153. The plurality of redistribution patterns 150 may further include a third group of redistribution patterns 155, and a second intermediate group of redistribution patterns 156 may be positioned between the third group of redistribution patterns 155 and the second group of redistribution patterns 153. The first intermediate group of redistribution patterns 151 may be positioned lower than the second group of redistribution patterns 153 and positioned higher than the first group of redistribution patterns 151.

The redistribution vias 160 may include at least one first redistribution via 161 extending through the first insulating layer 141, at least one first intermediate redistribution via 164 extending through the first intermediate insulating layer 144, at least one second redistribution via 163 extending through the second insulating layer 143, at least one second intermediate redistribution via 166 extending through the second intermediate insulating layer 146, and at least one third redistribution via 165 extending through the third insulating layer 145.

At least one first redistribution via 161 may connect the first redistribution pattern 151 and the external connection pattern 118 in the direction Z. When there are the first redistribution patterns 151, at least one first redistribution via 161 may connect the first redistribution patterns 151 in the direction Z. At least one first redistribution via 161 may be stacked in the direction Z.

At least one first intermediate redistribution via 164 may connect the first intermediate redistribution pattern 154 and the first redistribution pattern 151 in the direction Z. When there are the first intermediate redistribution patterns 154, at least one first intermediate redistribution via 164 may connect the first intermediate redistribution patterns 154 in the direction Z. At least one first intermediate redistribution via 164 may be stacked in the direction Z.

At least one second redistribution via 163 may connect the second redistribution pattern 153 and the first intermediate redistribution pattern 154 in the direction Z. When there are the second redistribution patterns 153, at least one second redistribution via 163 may connect the second redistribution patterns 153 in the direction Z. At least one second redistribution via 163 may be stacked in the direction Z.

At least one second intermediate redistribution via 166 may connect the second intermediate redistribution pattern 156 and the second redistribution pattern 153 in the direction Z. When there are the second intermediate redistribution patterns 156, at least one second intermediate redistribution via 166 may connect the second intermediate redistribution patterns 156 in the direction Z. At least one second intermediate redistribution via 166 may be stacked in the direction Z.

At least one third redistribution via 165 may connect the third redistribution pattern 155 and the second intermediate redistribution pattern 156 in the direction Z. When there are the third redistribution patterns 155, at least one third redistribution via 165 may connect the third redistribution patterns 155 in the direction Z. At least one third redistribution via 165 may connect the third redistribution pattern 155 and the redistribution connection pad 180 in the direction Z. At least one third redistribution via 165 may be stacked in the direction Z.

According to an embodiment, the first intermediate insulating layer 144 may be positioned on up to three first redistribution vias 161 stacked in the direction Z. As shown in FIG. 5, the first intermediate insulating layer 144 may be positioned on three first redistribution vias 161 stacked in the direction Z, but the present invention is not necessarily limited thereto. For example, the first intermediate insulating layer 144 may be positioned on one first redistribution via 161 or on two first redistribution vias 161 stacked in the direction Z.

According to an embodiment, the second intermediate insulating layer 146 may be positioned on up to three second redistribution vias 163 stacked in the direction Z. As shown in FIG. 5, the second intermediate insulating layer 146 may be positioned on three second redistribution vias 163 stacked in the direction Z, but the present invention is not necessarily limited thereto. For example, the second intermediate insulating layer 146 may be positioned on one second redistribution via 163 or on two second redistribution vias 163 stacked in the direction Z.

According to an embodiment, up to three third redistribution vias 165 may be stacked in the direction Z on the second intermediate insulating layer 146. As shown in FIG. 5, two third redistribution vias 165 may be stacked in the direction Z on the second intermediate insulating layer 146, but the present invention is not necessarily limited thereto. For example, one third redistribution vias 165 may be positioned on the second intermediate insulating layer 146, or two third redistribution vias 165 may be stacked in the direction Z.

According to an embodiment, wiring widths of the first intermediate redistribution pattern 154 and the second intermediate redistribution pattern 156 may be larger than wiring widths of the first redistribution pattern 151, the second redistribution pattern 153, and the third redistribution pattern 155. A width between wires of the first intermediate redistribution pattern 154 and the second intermediate redistribution pattern 156 may be larger than a width between wires of the first redistribution pattern 151, the second redistribution pattern 153, and the third redistribution pattern 155.

According to an embodiment, the redistribution vias 160 may include a series of redistribution vias having a common central axis and being stacked in the direction Z. The common central axis may extend along the direction Z. The series of redistribution vias stacked in the direction Z may include at least one first redistribution via 161 extending through the first insulating layer 141, at least one intermediate redistribution via 162 extending through the intermediate insulating layer 142, and at least one second redistribution via 163 extending through the second insulating layer 143. According to an embodiment, diameters (e.g., widths along the direction Y) of the first intermediate redistribution via 164 and the second intermediate redistribution via 166 may be larger than the diameters (e.g., widths along the direction Y) of the first redistribution via 161, the second redistribution via 163, and the third redistribution via 165.

According to an embodiment, surface roughness of a surface of the first intermediate insulating layer 144 in contact with the second insulating layer 143 may be about 3 μm or less, and surface roughness of a surface of the second intermediate insulating layer 146 in contact with the third insulating layer 145 may be about 3 μm or less.

As described above with reference to FIGS. 1 to 3, reliability of at least one first redistribution via 161, at least one second redistribution via 163, and at least one third redistribution via 165 stacked in the direction Z may be guaranteed up to three layers. According to an embodiment, the first intermediate insulating layer 144 having a higher thermal expansion coefficient than that of the first insulating layer 141 may be positioned on a first redistribution via 161 of up to three layers stacked in the direction Z, and a second redistribution via 163 of up to three layers stacked in the direction Z may be positioned on the first intermediate insulating layer 144. The second intermediate insulating layer 146 having a higher thermal expansion coefficient than that of the second insulating layer 143 may be positioned on a second redistribution via 163 of up to three layers stacked in the direction Z, and a third redistribution via 165 of up to three layers stacked in the direction Z may be positioned on the second intermediate insulating layer 146. In the embodiment of FIG. 5, the first intermediate insulating layer 144 may be positioned on the first redistribution via 161 of three layers, the second redistribution via 163 of three layers may be positioned on the first intermediate insulating layer 144, the second intermediate insulating layer 146 may be positioned on the second redistribution via 163 of three layers, and the third redistribution via 165 of two layers may be positioned on the second intermediate insulating layer 146.

The embodiment of FIG. 5 may have the same effect as that of the embodiment of FIG. 1 to FIG. 3. The semiconductor package 101 according to an embodiment may reduce warpage occurring while forming five or more redistribution patterns by including the first intermediate insulating layer 144 between the first insulating layer 141 and the second insulating layer 143, and the second intermediate insulating layer 146 between the second insulating layer 143 and the third insulating layer 145. According to an embodiment, multi-layer stacked redistribution vias connecting five or more redistribution patterns in a vertical direction may be reliably implemented, thereby improving electrical characteristics of the semiconductor package 100.

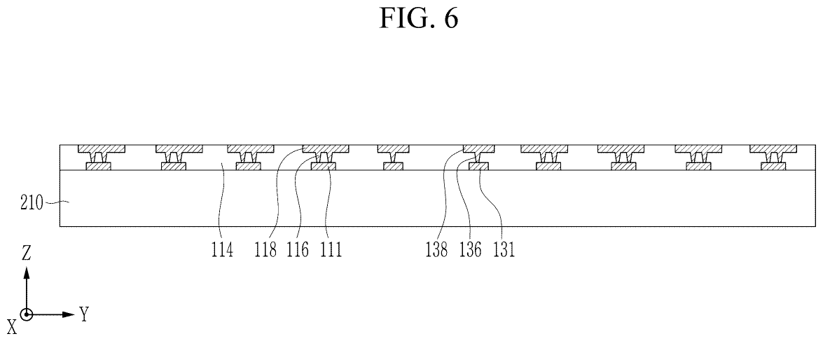

Hereinafter, a manufacturing method for the semiconductor package 100 of FIG. 1 will be described with reference to FIGS. 6 to 13.

FIG. 6 to FIG. 13 illustrate process cross-sectional views showing a manufacturing method for a semiconductor package according to an embodiment.

Referring to FIG. 6, the first external connection members 111, the external connection patterns 118, and the external connection vias 116 connecting each of the first external connection members 111 and each of the external connection patterns 118 may be formed on a carrier substrate 210. The first additional connection members 131, the additional connection patterns 138, and the additional connection vias 136 connecting each of the first additional connection members 131 and each of the additional connection patterns 138 may be formed on the carrier substrate 210 together with the first external connection members 111, the external connection patterns 118, and the external connection vias 116.

For example, after forming the external connection insulating layer 114 on the carrier substrate 210, the first external connection members 111 and the first additional connection members 131 may be formed after patterning the external connection insulating layer 114. The first external connection members 111 and the first additional connection members 131 may be formed through sputtering or electrolytic plating, for example. The first external connection members 111 and the first additional connection members 131 may include a metal (e.g., copper). For example, the first external connection members 111 and the first additional connection members 131 may include copper.

For example, a size (e.g., width along the direction Y) of each of the first additional connection members 131 may be smaller than a size (e.g., width along the direction Y) of each of the first external connection members 111.

Next, the external connection insulating layer 114 covering the first external connection members 111 and the first additional connection members 131 may be further formed, and the external connection insulating layer 114 may be patterned. In this case, a plurality of via holes may be formed on the first external connection members 111, and a single via hole may be formed on the first additional connection members 131 that are smaller than the first external connection members 111. Next, the external connection patterns 118, the external connection vias 116 respectively connected to the external connection patterns 118, the additional connection patterns 138, and the additional connection vias 136 respectively connected to the additional connection patterns 138 may be formed. For example, after forming a metal layer to fill insides of a plurality of via holes positioned on each of the first external connection members 111 and a single via hole positioned on each of the first additional connection members 131 and to cover the external connection insulating layer 114 through sputtering or electrolytic plating, the metal layer may be patterned to form the external connection patterns 118 and the additional connection patterns 138. Each of the external connection patterns 118 may be formed integrally with the external connection vias 116. The additional connection patterns 138 may respectively be integrally formed with the additional connections vias 136.

For example, a size (e.g., width along the direction Y) of each of the additional connection patterns 138 may be smaller than a size (e.g., width along the direction Y) of each of the external connection patterns 118.

According to an embodiment, the external connection patterns 118 may respectively be formed on the external connections via 116. According to an embodiment, each of the external connection patterns 118 may be formed on a pair of external connection vias 116 such that an upper surface of each of the external connection patterns 118 may be flatter than that in a comparative example where each of the external connection patterns 118 is formed on a single external connection via.

According to an embodiment, the additional connection patterns 138 may each be formed on a single additional connection via 136. Accordingly, flatness of an upper surface of each of the additional connection patterns 138 may be reduced, but a size of each of the additional connection patterns 138 is smaller than that of each of the external connection patterns 118, so the flatness of the upper surface may have a relatively small effect on a subsequent process.

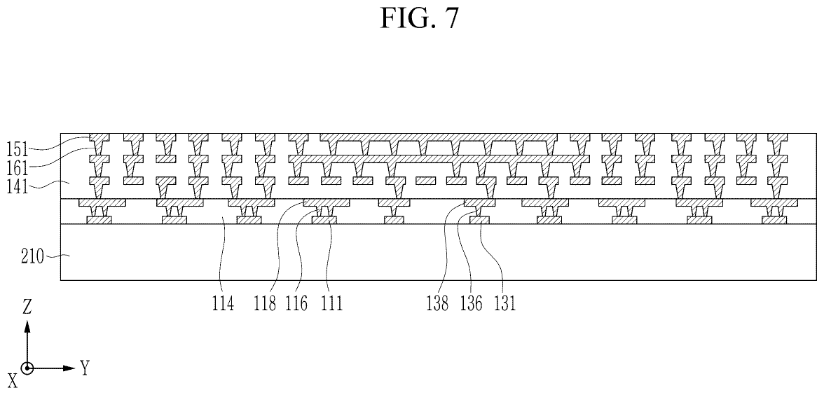

Referring to FIG. 7, the first insulating layer 141 may be formed on the external connection patterns 118, and at least one first redistribution via 161 and at least one first redistribution pattern 151 surrounded by the first insulating layer 141 may be formed.

First, the first insulating layer 141 covering upper surfaces of the external connection patterns 118 and the external connection insulating layer 114 may be formed. For example, the first insulating layer 141 may be formed through a deposition or coating process. For example, the first insulating layer 141 may include or be formed of a photo imageable dielectric (PID). Next, the first insulating layer 141 may be patterned to form via holes, and a metal layer may be formed to fill insides of the via holes and cover the first insulating layer 141, and then, the metal layer may be patterned to form the first redistribution via 161 and the first redistribution pattern 151. The first redistribution via 161 and the first redistribution pattern 151 may include copper, for example. The first redistribution via 161 and the first redistribution pattern 151 may be integrally formed, but the present invention is not necessarily limited thereto.

Next, after additionally forming the first insulating layer 141, a process of patterning the first insulating layer 141 and forming the first redistribution via 161 and the first redistribution pattern 151 may be repeated. For example, by repeating the above-described process three times, the first redistribution via 161 of three layers and three first redistribution pattern 151 may be formed, as shown in FIG. 7, which are stacked in the direction Z.

In some embodiments, for example, the first insulating layer 141 may be formed on the plurality of external connection patterns 118. A first group of redistribution vias 161 and a first group of redistribution patterns 151 may be formed such that the first group of redistribution vias 161 and the first group of redistribution patterns 151 are surrounded by the first insulating layer 141.

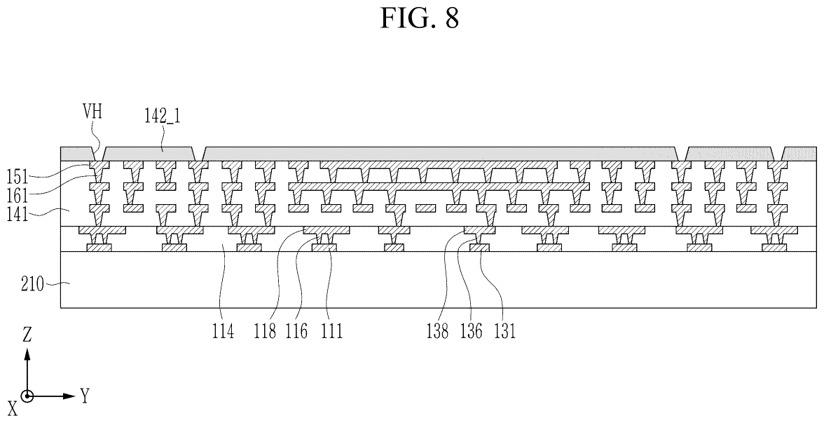

Referring to FIG. 8, a first sub-insulating layer 142_1 may be formed on at least one first redistribution pattern 151, and the first sub-insulating layer 142_1 may be patterned to form at least one via hole VH. For example, the first sub-insulating layer 142_1 may be formed by laminating a sheet-shaped insulating layer on at least one first redistribution pattern 151. The sheet-shaped insulating layer may include, e.g., Ajinomoto Build-up Film® (ABF) or a prepreg. The ABF or prepreg may have a lower coefficient of thermal expansion than that of a photo imageable dielectric (PID). Accordingly, the intermediate insulating layer 142 formed by laminating a sheet-shaped insulating layer several times may include a material having a lower thermal expansion coefficient than that of the first insulating layer 141.

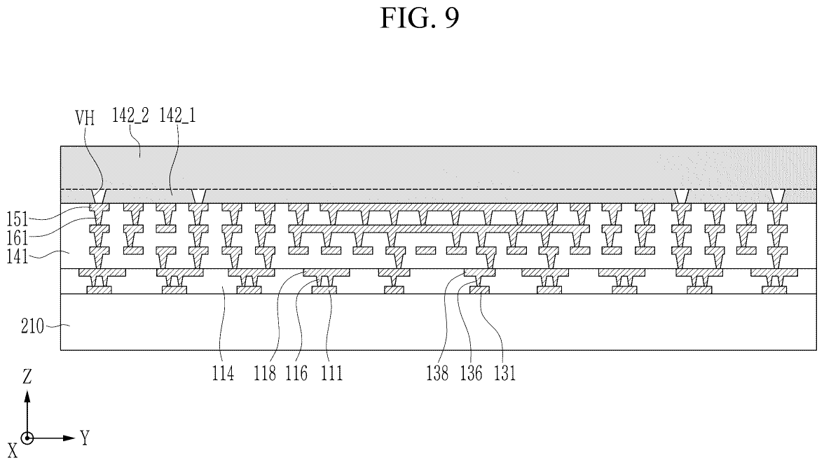

Referring to FIG. 9, a second sub-insulating layer 142_2 covering at least one via hole VH may be formed. For example, a sheet-shaped insulating layer may be additionally laminated on the first sub-insulating layer 142_1 to form the second sub-insulating layer 142_2. In this case, multiple sheet-shaped insulating layers may be laminated such that the second sub-insulating layer 142_2 has a thickness (length along the direction Z) that is at least twice that of the first redistribution pattern 151.

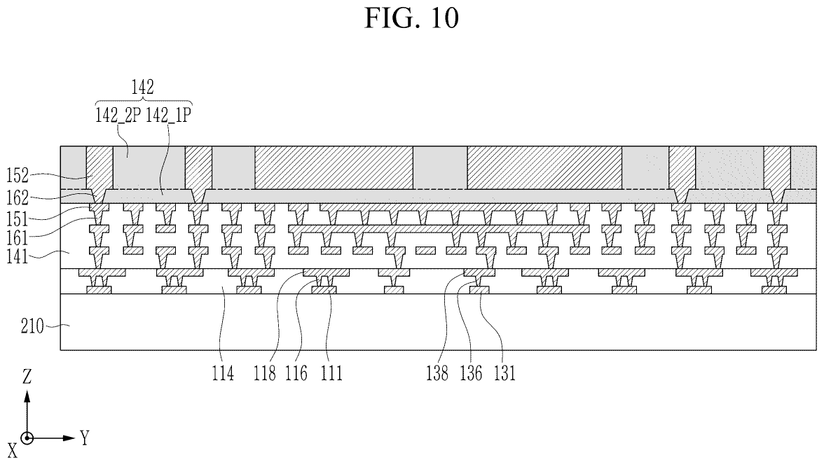

Referring to FIG. 10, openings may be formed by patterning the second sub-insulating layer 142_2. After patterning the second sub-insulating layer 142_2, a plating process may be performed thereby forming a first conductive material to fill the via holes VH and forming a second conductive material to fill the openings. The first and second conductive materials are formed by performing a plating process. For example, the plating process may be performed to form at least one intermediate redistribution via 162 and at least one intermediate redistribution pattern 152. For example, the second sub-insulating layer 142_2 may be patterned to form openings in the second sub-insulating layer 142_2. At least one via hole VH may be exposed through the openings in the second sub-insulating layer 142_2. A metal material may be filled into the openings of the second sub-insulating layer 142_2 and at least one via hole VH to form at least one intermediate redistribution via 162 and at least one intermediate redistribution pattern 152. At least one intermediate redistribution via 162 and at least one intermediate redistribution pattern 152 may be formed through a plating process. At least one intermediate redistribution via 162 and at least one intermediate redistribution pattern 152 may include, e.g., copper.

For example, the via holes VH may be filled by a first conductive material, and the openings in the second sub-insulating layer 142_2 may be filled by a second conductive material. The first and second conductive materials may be the same as each other.

A wiring width of the at least one intermediate redistribution pattern 152 and a wiring width therebetween may be greater than a wiring width the at least one first redistribution via 161 and a wiring width therebetween. Herein, the wiring width and the inter-wiring space may indicate a length along the direction Y. A diameter (e.g., width along the direction Y) of at least one intermediate redistribution via 162 may be larger than a diameter (e.g., width along the direction Y) of at least one first redistribution via 161.

As described above, the second sub-insulating layer 142_2 may have a thickness that is at least twice that of the first redistribution pattern 151. Accordingly, a depth (length in the direction Z) of the openings of the second sub-insulating layer 142_2 may also be at least twice a thickness (length in the direction Z) of the first redistribution pattern 151. According to an embodiment, at least one intermediate redistribution pattern 152 filling insides of the openings of the second sub-insulating layer 142_2 may be formed thicker than at least one first redistribution pattern 151.

Hereinafter, the intermediate insulating layer 142 may include a patterned first sub-insulating layer 142_1P and a patterned second sub-insulating layer 142_2P through the processes illustrated in FIGS. 8 to 10.

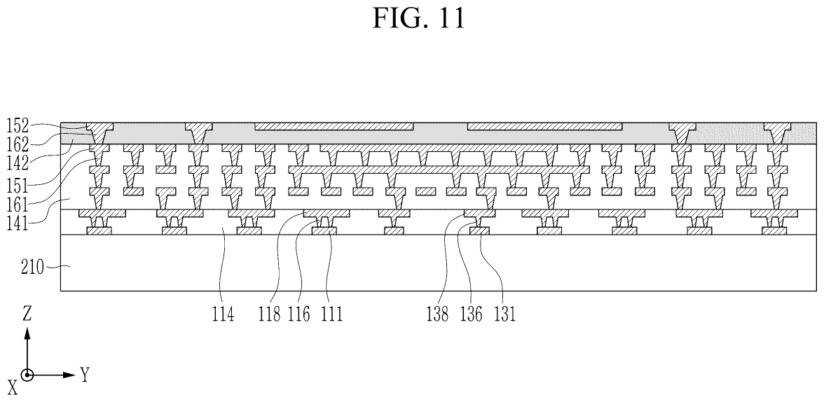

Referring to FIG. 11, thicknesses of the intermediate insulating layer 142 and the at least one intermediate redistribution pattern 152 may be reduced by grinding surfaces of the intermediate insulating layer 142 and the at least one intermediate redistribution pattern 152. For example, after grinding, the thickness of at least one intermediate redistribution pattern 152 may be similar to the thickness of at least one first redistribution pattern 151.

A grinding process may be used to flatten the surfaces of the intermediate insulating layer 142 and at least one intermediate redistribution pattern 152. According to an embodiment, surface roughness of a surface of the intermediate insulating layer 142 may be about 3 μm or less.

In some embodiments, for example, the intermediate insulating layer 142 formed by laminating a sheet-shaped insulating layer on the first group of redistribution patterns 151. An intermediate group of redistribution vias 162 and an intermediate group of redistribution patterns 152 may be formed such that the intermediate group of redistribution vias 162 and the intermediate group of redistribution patterns 152 are surrounded by the intermediate insulating layer 142.

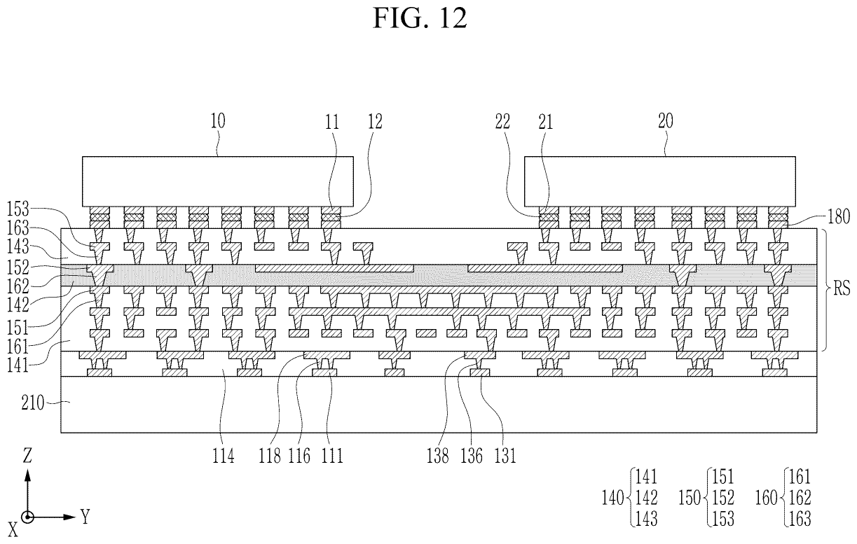

Referring to FIG. 12, the second insulating layer 143 may be formed on at least one intermediate redistribution pattern 152, and at least one second redistribution via 163 and at least one second redistribution pattern 153 surrounded by the second insulating layer 143 may be formed.

First, the second insulating layer 143 covering at least one intermediate redistribution pattern 152 and an upper surface of the intermediate insulating layer 142 may be formed. For example, the second insulating layer 143 may be formed through a deposition or coating process. For example, the second insulating layer 143 may include a photo imageable dielectric (PID). Next, the second insulating layer 143 may be patterned to form via holes, and a metal layer may be formed to fill insides of the via holes and cover the second insulating layer 143, and then, the metal layer may be patterned to form the second redistribution via 163 and the second redistribution pattern 153. The second redistribution via 163 and the second redistribution pattern 153 may include copper, for example. The second redistribution via 163 and the second redistribution pattern 153 may be integrally formed, but the present invention is not necessarily limited thereto.

Next, after additionally forming the second insulating layer 143, a process of patterning the second insulating layer 143 and forming the second redistribution via 163 may be repeated. For example, by repeating the above-described process one more time, the second redistribution via 163 of two layers and one second redistribution pattern 153 may be formed, as shown in FIG. 12, which are stacked in the direction Z.

In some embodiments, for example, the second insulating layer 143 may be formed on the intermediate group of redistribution patterns 152. A second group of redistribution vias 163 and a second group of redistribution patterns 153 may be formed such that the second group of redistribution vias 163 and the second group of redistribution patterns 153 are surrounded by the second insulating layer 143.

According to the above-described processes, the redistribution layer RS may be formed. The redistribution layer RS may include a first insulating layer 141, a second insulating layer 143, and an intermediate insulating layer 142 positioned between the first insulating layer 141 and the second insulating layer 143. The intermediate insulating layer 142 may include a different material from those of the first insulating layer 141 and the second insulating layer 143. According to an embodiment, the intermediate insulating layer 142 may include a material having a lower thermal expansion coefficient than those of the first insulating layer 141 and the second insulating layer 143.

The redistribution layer RS may include three first redistribution patterns 151 stacked in the direction Z and the first redistribution via 161 of three layers stacked in the direction Z. Three first redistribution patterns 151 and the first redistribution via 161 of three layers may be surrounded by the first insulating layer 141. The redistribution layer RS may include one intermediate redistribution pattern 152 and an intermediate redistribution via 162 of one layer. One intermediate redistribution pattern 152 and the intermediate redistribution via 162 of one layer may be surrounded by the intermediate insulating layer 142. The redistribution layer RS may include one second redistribution pattern 153 and the second redistribution via 163 of two layers stacked in the direction Z. One second redistribution pattern 153 and the second redistribution via 163 of two layers may be surrounded by the second insulating layer 143.

However, the invention is not limited thereto. According to an embodiment, a number of at least one first redistribution via 161 stacked in the direction Z and a number of at least one second redistribution via 163 stacked in the direction Z may each be up to three layers, and thus may be variously changed within a corresponding range.

The redistribution layer RS according to an embodiment may include a series of redistribution vias having a common central axis and being stacked in the direction Z. By the series of redistribution vias, multiple redistribution patterns stacked in the direction Z included in the redistribution layer RS may be connected by a shortest path. Accordingly, the electric characteristics of the semiconductor package 100 manufactured by performing subsequent processes may be improved.

In some embodiments, for example, the first group of redistribution vias 161 may include a first plural sets of redistribution vias. Each of the first plural sets of redistribution vias may include first individual redistribution vias located at the same height level as each other in a direction perpendicular to the surface of the intermediate insulating layer 142. The second group of redistribution vias 163 may include a second plural sets of redistribution vias. Each of the second plural sets of redistribution vias may include second individual redistribution vias located at the same height level as each other in a direction perpendicular to the surface of the intermediate insulating layer 142. A number of the first plural sets of redistribution vias is from one to three, and a number of the second plural sets of redistribution vias is from one to three.

Next, the redistribution connection pads 180 may be formed on at least one second redistribution pattern 153. The redistribution connection pads 180 may be connected to at least one second redistribution pattern 153 by at least one second redistribution via 163.

Next, a plurality of semiconductor chips 10 and 20 may be stacked on the redistribution connection pads 180. Chip connection terminals 12 and 22 of the plurality of semiconductor chips 10 and 20 may be bonded to a corresponding one of the redistribution connection pads 180.

connection members (chip connection terminals) 12 and 22 of the respective semiconductor chips 10 and 20 may be bonded on the redistribution connection pads 180. For example, the semiconductor chips 10 and 20 may include a first semiconductor chip 10 and a second semiconductor chip 20. A plurality of first connection pads 11 may be arranged on a first surface of the first semiconductor chip 10, and a plurality of first connection members 12 may be respectively arranged on the first connection pads 11. A plurality of second connection pads 21 may be arranged on a first surface of the second semiconductor chip 20, and a plurality of second connection members 22 may be respectively arranged on the second connection pads 21. The first connection members 12 may be bonded to some of the redistribution connection pads 180, and the second connection members 22 may be bonded to some of the redistribution connection pads 180.

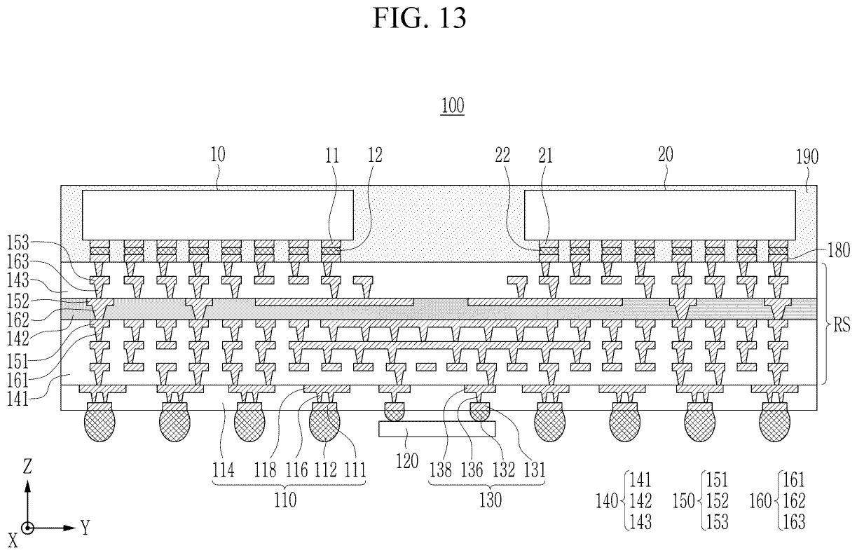

Referring to FIG. 13, the molding member 190 covering the semiconductor chips 10 and 20 may be formed on the redistribution layer RS. The molding member 190 may be formed through a transfer molding or compression molding process, for example. The molding member 190 may include, e.g., an epoxy molding compound (EMC).

The molding member 190 may fill a space between lower surfaces of the semiconductor chips 10 and 20 and an upper surface of the redistribution layer RS. For example, the molding member 190 may surround the first connection pads 11, the second connection pads 21, the first connection members 12, and the second connection members 22.

Next, after removing the carrier substrate 210, the second external connection members 112 may be respectively attached on the first external connection members 111, and the second additional connection members 132 may be respectively attached on the first additional connection members 131. Each of the second external connection members 112 and the first additional connection members 131 may be, e.g., a solder ball. The second external connection members 112 may include, e.g., at least one of tin, lead, nickel, copper, or an alloy thereof.

For example, each of the first additional connection members 131 may be smaller in size (e.g., width along the direction Y and the direction Z) than each of the second external connection members 112.

The external connection structure 110 may be formed by respectively attaching the second external connection members 112 to the first external connection members 111. The external connection structure 110 may include an external connection insulating layer 114, a plurality of external connection patterns 118, a plurality of external connection vias 116, a plurality of first external connection members 111, and a plurality of second external connection members 112.

The external connection structure 110 may be formed by respectively attaching the second additional connection members 132 to the first additional connection members 131. The additional connection structure 130 may include a plurality of additional connection patterns 138, a plurality of first additional connection members 131, a plurality of second additional connection members 132, and additional connection vias 136.

Next, the passive element 120 may be bonded to the second additional connection members 132. The passive element 120 may include, e.g., a decoupling capacitor. For example, power integrity of the semiconductor package 100 may be improved by mounting a decoupling capacitor on a first surface of the semiconductor package 100.

According to the manufacturing processes of FIG. 6 to FIG. 13, the semiconductor package 100 according to an embodiment may be manufactured. According to an embodiment, the semiconductor package 100 may include an intermediate insulating layer 142 between the first insulating layer 141 and the second insulating layer 143, the intermediate insulating layer 142 including a different material from those of the first insulating layer 141 and the second insulating layer 143. The intermediate insulating layer 142 may be surrounded by the first insulating layer 141, and may be formed on the first redistribution via 161 of three layers stacked in the direction Z. Accordingly, undulation accumulated in the first insulating layer 141 may be reset.

According to an embodiment, the intermediate insulating layer 142 may include a material having a lower thermal expansion coefficient than those of the first insulating layer 141 and the second insulating layer 143. Accordingly, warping phenomenon in subsequent processes may be reduced.

According to an embodiment, the intermediate insulating layer 142 may be formed by laminating multiple sheet-shaped insulating layers, and then grinding them, so that an upper surface of the intermediate insulating layer 142 may be flat.

In summary, the manufacturing method of semiconductor package 100 according to an embodiment may reduce warpage occurring while forming five or more redistribution patterns. In accordance with the manufacturing method of semiconductor package 100 according to an embodiment, multi-layer stacked redistribution vias connecting five or more redistribution patterns in a vertical direction may be reliably implemented, thereby improving electrical characteristics of the semiconductor package 100.

While this disclosure has been described in connection with what is presently considered to be practical embodiments, it is to be understood that the invention is not limited to the disclosed embodiments, but, on the contrary, is intended to cover various modifications and equivalent dispositions included within the spirit and scope of the appended claims.

What is claimed is:

1. A semiconductor package comprising:
a redistribution layer including a first surface and a second surface facing away from each other;
an external connection structure on the first surface;
a plurality of semiconductor chips arranged on the second surface; and
a molding material covering the plurality of semiconductor chips,
wherein the redistribution layer includes a plurality of redistribution patterns, a plurality of redistribution vias, and an insulating layer surrounding the plurality of redistribution patterns and the plurality of redistribution vias,
wherein each of the plurality of redistribution vias is connected to a corresponding one of the plurality of redistribution patterns,
wherein the insulating layer includes a first insulating layer, a second insulating layer, and an intermediate insulating layer positioned between the first insulating layer and the second insulating layer,
wherein the plurality of redistribution patterns includes a first group of redistribution patterns, a second group of redistribution patterns, and an intermediate group of redistribution patterns positioned between the first group of redistribution patterns and the second group of redistribution patterns,
wherein the intermediate insulating layer includes a material that is different from those of the first insulating layer and the second insulating layer, and
wherein the intermediate insulating layer surrounds sidewalls of the intermediate group of redistribution patterns.

2. The semiconductor package of claim 1, wherein:
the plurality of redistribution patterns include at least five sets of redistribution patterns, which are stacked sequentially,
the plurality of redistribution vias include plural sets of redistribution vias,
each of the plural sets of redistribution vias includes individual redistribution vias located at the same height level as each other, in a direction perpendicular to the first surface,
one to three sets of the plural sets of redistribution vias are positioned higher than the intermediate insulating layer, and
one to three sets of the plural sets of redistribution vias are positioned lower than the intermediate insulating layer.

3. The semiconductor package of claim 1, wherein the intermediate insulating layer includes an Ajinomoto Build-up Film® (ABF) or a prepreg.

4. The semiconductor package of claim 1, wherein:
sidewalls of the first group of redistribution patterns and sidewalls of the second group of redistribution patterns are surrounded by the first insulating layer or the second insulating layer,
each of the plurality of redistribution patterns has a minimum width, and a smallest one of the minimum widths of the intermediate group of redistribution patterns is larger than a smallest one of the minimum widths of the first group of redistribution patterns and a smallest one of the minimum widths of the second group of redistribution patterns, and
each pair of horizontally adjacent redistribution patterns of the plurality of redistribution patterns has a minimum inter-wiring space, and a smallest one of the minimum inter-wiring spaces of the intermediate group of redistribution patterns is larger than a smallest one of the minimum inter-wiring spaces of the first group of redistribution patterns and is larger than a smallest one of the minimum inter-wiring spaces of the second group of redistribution patterns.

5. The semiconductor package of claim 1, wherein some redistribution patterns of the intermediate group of redistribution patterns are configured to be electrically connected to ground.

6. The semiconductor package of claim 1, wherein:
the intermediate insulating layer has a rough surface which is in contact with the second insulating layer, and
an average roughness of the rough surface is equal to or less than 3 μm.

7. The semiconductor package of claim 1, wherein:
the plurality of redistribution vias include a series of redistribution vias,
the series of redistribution vias have the same central axis as each other in a direction that is perpendicular to the first surface,
the series of redistribution vias are stacked in a direction that is perpendicular to the first surface, and
the series of redistribution vias has a first redistribution via having a sidewall surrounded by the intermediate insulating layer.

8. The semiconductor package of claim 7, wherein:
the series of redistribution vias has second redistribution vias other than the first redistribution via,
the second redistribution vias have sidewalls surrounded by the first insulating layer or the second insulating layer, and
a diameter of the first redistribution via is larger than diameters of the second redistribution vias.

9. The semiconductor package of claim 1,
wherein the external connection structure includes:
a plurality of external connection patterns arranged on the first surface,
an external connection insulating layer covering the plurality of external connection patterns,
a plurality of external connection pads positioned on the external connection insulating layer,
a plurality of external connection terminals respectively positioned on the plurality of external connection pads, and
a plurality of external connection vias extending through the external connection insulating layer, and
wherein each of the plurality of external connection vias is electrically connected to a corresponding one of the external connection patterns and a corresponding one of the external connection pads.

10. The semiconductor package of claim 1, further comprising a passive device mounted on one surface of the semiconductor package on which external connection terminals are disposed.

11. A semiconductor package comprising:
a redistribution layer including a first surface and a second surface facing away from each other;
an external connection structure on the first surface;
a plurality of semiconductor chips arranged on the second surface; and
a molding material covering the plurality of semiconductor chips,
wherein the redistribution layer includes a plurality of redistribution patterns, a plurality of redistribution vias, and an insulating layer surrounding the plurality of redistribution patterns and the plurality of redistribution vias,
wherein each of the plurality of redistribution vias is connected to a corresponding one of the plurality of redistribution patterns,
wherein the insulating layer includes a first insulating layer, a second insulating layer, and an intermediate insulating layer positioned between the first insulating layer and the second insulating layer,
wherein the plurality of redistribution patterns includes a first group of redistribution patterns, a second group of redistribution patterns, and an intermediate group of redistribution patterns,
wherein the intermediate group of redistribution patterns is positioned lower than the second group of redistribution patterns and positioned higher than the first group of redistribution patterns,
wherein the first insulating layer surrounds sidewalls of the first group of redistribution patterns, the second insulating layer surrounds sidewalls of the second group of redistribution patterns, and the intermediate insulating layer surrounds sidewalls of the intermediate group of redistribution patterns, and
wherein a material of the intermediate insulating layer has a lower coefficient of thermal expansion than materials of the first insulating layer and the second insulating layer.

12. The semiconductor package of claim 11, wherein:
the plurality of redistribution patterns include at least five sets of redistribution patterns, which are stacked sequentially,
the plurality of redistribution vias include plural sets of redistribution vias,
each of the plural sets of redistribution vias includes individual redistribution vias located at the same height level as each other, in a direction perpendicular to the first surface,
one to three sets of redistribution vias are positioned higher than the intermediate insulating layer, and
one to three sets of redistribution vias are positioned lower than the intermediate insulating layer.

13. The semiconductor package of claim 11, wherein:
the first insulating layer and the second insulating layer include a photo imageable dielectric (PID), and
the intermediate insulating layer includes an Ajinomoto Build-up Film® (ABF) or a prepreg.

14. The semiconductor package of claim 11, wherein:
each of the plurality of redistribution patterns has a minimum width, and a smallest one of the minimum widths of the intermediate group of redistribution patterns is larger than a smallest one of the minimum widths of the first group of redistribution patterns and a smallest one of the minimum widths of the second group of redistribution patterns, and
each of adjacent pairs of the plurality of redistribution patterns has a minimum inter-wiring space, and a smallest one of the minimum inter-wiring spaces of the intermediate group of redistribution patterns is larger than a smallest one of the minimum widths of the first group of redistribution patterns and a smallest one of the minimum widths of the second group of redistribution patterns.

15. The semiconductor package of claim 11,
wherein the plurality of redistribution vias include a series of redistribution vias,
wherein the series of redistribution vias have the same central axis as each other in a direction that is perpendicular to the first surface
wherein the series of redistribution vias are stacked in a direction that is perpendicular to the first surface, and
wherein the series of redistribution vias include:
a first redistribution via extending through the first insulating layer,
a second redistribution via extending through the intermediate insulating layer, and
a third redistribution via extending through the second insulating layer.

16. The semiconductor package of claim 15, wherein a diameter of the second redistribution via is larger than diameters of each of the first and third redistribution vias.

17. A semiconductor package comprising:
a redistribution layer including a first surface and a second surface facing away from each other; and
a plurality of semiconductor chips arranged on the second surface,
wherein:
the redistribution layer includes a plurality of redistribution pattern layers, a plurality of redistribution via layers, and an insulating layer surrounding the plurality of redistribution pattern layers and the plurality of redistribution via layers,
the insulating layer includes a first insulating layer, a second insulating layer, and an intermediate insulating layer positioned between the first insulating layer and the second insulating layer,
the plurality of redistribution pattern layers includes a first group of redistribution patterns, a second group of redistribution patterns, and an intermediate group of redistribution patterns,
the intermediate group of redistribution patterns is positioned lower than the second group of redistribution patterns and positioned higher than the first group of redistribution patterns,
the first insulating layer surrounds sidewalls of the first group of redistribution patterns, the second insulating layer surrounds sidewalls of the second group of redistribution patterns, and the intermediate insulating layer surrounds sidewalls of the intermediate group of redistribution patterns,
the intermediate insulating layer is formed of a first material having a first coefficient of thermal expansion,
the first insulating layer is formed of a second material having a second coefficient of thermal expansion,
the second insulating layer is formed of a third material having a third coefficient of thermal expansion,
the first coefficient of thermal expansion is less than the second coefficient of thermal expansion and the third coefficient of thermal expansion,
the intermediate group of redistribution patterns include one or more ground patterns configured to be electrically connected to ground.

18. The semiconductor package of claim 17, wherein the intermediate insulating layer includes an Ajinomoto Build-up Film® (ABF) or a prepreg.

19. The semiconductor package of claim 18, wherein the second material is the same as the third material.

20. The semiconductor package of claim 17, wherein:
each pattern of the plurality of redistribution pattern layers has a minimum width,
a smallest one of the minimum widths of the intermediate group of redistribution patterns is greater than a smallest one of the minimum widths of the first group of redistribution patterns and a smallest one of the minimum widths of the second group of redistribution patterns.
